(19) United States
(12) Patent Application Publication
(10) Pub. No.: US 2024/0258086 A1
(43) Pub. Date: Aug. 1, 2024

(54) FILM FORMATION METHOD AND FILM FORMATION APPARATUS

(71) Applicant: TOKYO ELECTRON LIMITED, Tokyo (JP)

(72) Inventors: Tadashi MITSUNARI, Nirasaki City, Yamanashi (JP); Hiroki ARAI, Nirasaki City, Yamanashi (JP)

(21) Appl. No.: 18/565,489

(22) PCT Filed: May 24, 2022
(86) PCT No.: PCT/JP2022/021240

§ 371 Date: Nov. 29, 2023

(30) Foreign Application Priority Data
Jun. 7, 2021 (JP) 2021-095415

(51) Int. Cl. H01J 37/32; C23C 16/26; C23C 16/44; C23C 16/503; C23C 16/509; C23C 16/515; C23C 16/52; H01L 21/02

(52) U.S. Cl. CPC H01J 37/32834; C23C 16/26; C23C 16/4408; C23C 16/503; C23C 16/509; C23C 16/515; C23C 16/52; H01J 37/32146; H01J 37/32449; H01J 2237/3321; H01L 21/02115; H01L 21/02274

(57) ABSTRACT

A film formation method comprising: placing a substrate on a substrate table provided in a treatment container, discharging air inside the treatment container to reduce pressure therein; producing plasma by applying a combination of a high-frequency power and a direct-current pulsed voltage to the substrate table while supplying a treatment gas containing a carbon-containing gas into the pressure-reduced treatment container, to form a carbon film on the substrate.

### TECHNICAL FIELD

The present disclosure relates to a film forming method and a film forming apparatus.

### BACKGROUND

With the recent development of semiconductor microlithography technology, ArF resist patterned with short-wavelength light is being used. Since the ArF resist has low dry etching resistance, an amorphous carbon has been proposed as a hard mask with high dry etching resistance (Patent Documents 1 and 2). Patent Documents 1 and 2 describe forming such amorphous carbon as a film using a plasma CVD method.

### PRIOR ART DOCUMENTS

### Patent Documents

Patent Document 1: Japanese Laid-open Patent Publication No. 2002-194547
Patent Document 2: Japanese Laid-open Patent Publication No. 2002-12972

### Non-Patent Documents

Non-Patent Document 1: Robertson, J., “Diamond-like amorphous carbon,” Materials Science and Engineering R 37: 129-281, 2002
Non-Patent Document 2: Park, S. J. et al., “Diamond-like amorphous carbon layer film by an inductively coupled plasma system for next generation etching hard mask”

### SUMMARY

### Problems to Be Resolved by the Invention

The present disclosure provides a film forming method and a film forming apparatus capable of forming a carbon film with high density and low stress.

### Means for Solving the Problems

A film forming method according to an aspect of the present disclosure includes: placing a substrate on a substrate placement table provided in a processing container; exhausting and depressurizing inside of the processing container; and forming a carbon film on the substrate by applying superimposed high frequency power and direct current pulse voltage to the substrate placement table to generate plasma while supplying a processing gas containing a carbon-containing gas into the depressurized processing container.

### Effect of the Invention

According to the present disclosure, a film forming method and a film forming apparatus that can obtain a carbon film with high density and low stress are provided.

### BRIEF DESCRIPTION OF THE DRAWINGS

FIG. 1 is a cross-sectional view schematically illustrating an example of a film forming apparatus that performs a film forming method according to an embodiment.

FIG. 2 is a flowchart illustrating a flow of the film forming method according to the first embodiment.

FIG. 3 is a cross-sectional view illustrating an example of a structure of a substrate used in the film forming method according to the first embodiment.

FIG. 4 is a cross-sectional view illustrating a state in which a carbon film is formed on the substrate of FIG. 3.

FIG. 5 is a diagram illustrating a voltage waveform applied when high frequency power and a direct current pulse voltage are superimposed at the time of forming a carbon film.

FIG. 6 is a diagram illustrating an ion energy distribution of plasma when a carbon film is formed.

FIG. 7 is a diagram illustrating a relationship between RF power and ion energy at a high-energy side end position, a middle position (peak position), and a low-energy side end position in a first ion energy distribution region by high frequency power when the high frequency power and the direct current pulse voltage are superimposed and applied, with RF power on a horizontal axis and ion energy on a vertical axis.

FIG. 8 is a diagram illustrating a relationship between RF power and film density when high frequency power and direct current pulse voltage are superimposed and applied to a substrate placement table.

FIG. 9 is a diagram illustrating a relationship between RF power and film stress when high frequency power and direct current pulse voltage are superimposed and applied to a substrate placement table.

FIG. 10 is a diagram illustrating a relationship between RF power for bias and film stress (compressive stress) when two frequencies including high frequency power for film formation and high frequency power for bias are applied to the substrate placement table.

FIG. 11 is a diagram illustrating a relationship between a value of the direct current pulse voltage and the film stress (compressive stress) when the two frequencies including the high frequency power for film formation and the high frequency power for bias are applied to the substrate placement table.

FIG. 12 is a diagram illustrating results of evaluating the dependency of a duty ratio at a frequency of 500 kHz of the direct current pulse.

FIG. 13 is a diagram illustrating results of an experiment of pulse frequency dependence at the same duty ratio of 10% in order to evaluate effects of a pulse frequency.

FIG. 14 is a flowchart illustrating a flow of a film forming method according to a second embodiment.

FIG. 15 is a cross-sectional view illustrating an example of a structure of a substrate used in the film forming method according to the second embodiment.

FIG. 16 is a cross-sectional view illustrating a state in which an initial carbon film is formed on the substrate of FIG. 15.

FIG. 17 is a cross-sectional view illustrating a state in which a main carbon film is formed on the initial carbon film of the substrate of FIG. 16.

### DETAILED DESCRIPTION

Hereinafter, embodiments will be described with reference to the accompanying drawings.

### Example of Film Forming Apparatus

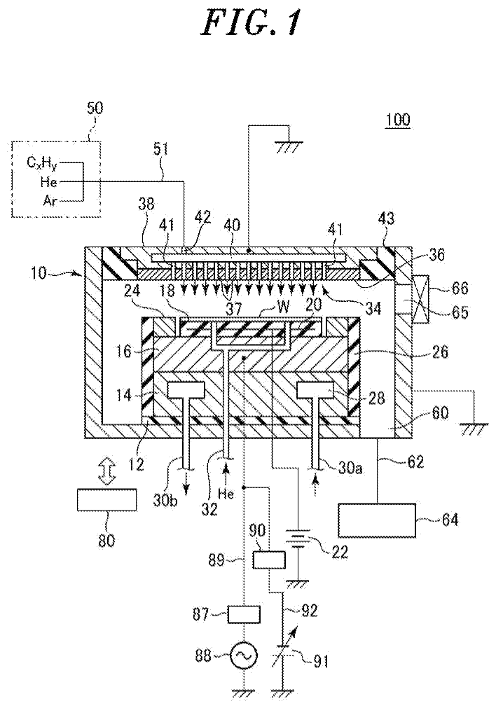

FIG. 1 is a cross-sectional view schematically illustrating an example of a film forming apparatus in which a film forming method according to an embodiment is performed.

A film forming apparatus 100 of this example forms a carbon film suitable for a hard mask on a substrate W, and is configured as a capacitively coupled plasma processing apparatus. The substrate W may be, for example, a semiconductor wafer, but is not limited thereto.

This film forming apparatus 100 has a substantially cylindrical shape and includes a processing container (chamber) 10 made of metal, such as aluminum of which a surface is anodized. This processing container 10 is securely grounded.

A cylindrical metal support 14 is disposed at a bottom of the processing container 10 via an insulating plate 12 made of ceramics or the like, and a substrate placement table 16 made of metal, such as aluminum, is provided on this support 14. The substrate placement table 16 constitutes a lower electrode. The substrate placement table 16 includes, on an upper surface thereof, an electrostatic chuck 18 that adsorbs and holds the substrate W with electrostatic force. This electrostatic chuck 18 has a structure in which an electrode 20 is provided inside an insulator, and when a direct current voltage from an adsorption direct current power supply 22 is applied to the electrode 20, the substrate (W) is adsorbed and held by electrostatic force such as Coulomb force.

A conductive focus ring 24 made of, for example, silicon for improving uniformity of plasma processing is disposed around the electrostatic chuck 18. A cylindrical inner wall member 26 made of an insulator, for example, quartz, is provided on side surfaces of the substrate placement table 16 and the support 14.

A refrigerant chamber 28 is provided inside the support 14. A coolant such as cooling water is circulated and supplied to this refrigerant chamber 28 from an externally provided chiller unit (not illustrated) via pipes 30a and 30b, and a processing temperature for the substrate W on the substrate placement table 16 is controlled by the refrigerant.

Further, a heat transfer gas, such as He gas, from a heat transfer gas supply mechanism (not illustrated) is supplied between an upper surface of the electrostatic chuck 18 and a back surface of a semiconductor wafer W through a gas supply line 32.

An upper electrode 34 is provided above the substrate placement table (lower electrode) 16, to face the substrate placement table 16. A space between the upper electrode 34 and the substrate placement table (lower electrode) 16 becomes a plasma generation space. The upper electrode 34 is grounded.

This upper electrode 34 is supported on an upper portion of the processing container 10 via an insulating shielding member 43. The upper electrode 34 constitutes a surface facing the substrate placement table 16 and includes an electrode plate 36 having a plurality of ejection holes 37, and an electrode support 38 having a water-cooling structure that detachably supports the electrode plate 36. A gas diffusion chamber 40 is provided inside the electrode support 38, and a plurality of gas flow holes 41 communicating with gas ejection holes 37 extend downward from this gas diffusion chamber 40. A gas introduction port 42 that guides the processing gas to the gas diffusion chamber 40 is formed in the electrode support 38, and a gas pipe 51 connected to a gas supply 50 (described below) is connected to this gas introduction port 42. A processing gas supplied from the gas supply 50 is supplied to the gas diffusion chamber 40, and ejected toward the substrate placement table 16 that is the lower electrode in the processing container 10 through the gas flow holes 41 and the gas ejection holes 37. That is, the upper electrode 34 is configured as a shower head.

The gas supply 50 includes a plurality of gas supply sources that supply, as processing gases, a carbon-containing gas (CₓH_{y}), and a He gas and an Ar gas that are rare gases, and a plurality of gas supply pipes for supplying the respective gases from the plurality of gas supply sources. Each gas supply pipe is provided with an opening and closing valve and a flow rate controller such as a mass flow controller (not illustrated), which make it possible to supply a gas or stop the supply and control a flow rate of each gas. Further, in this example, the He gas and the Ar gas are supplied as rare gases, but the present disclosure is not limited thereto, and for example, only the Ar gas may be used, or other rare gases may be used. Further, the processing gas may be only a carbon-containing gas.

An exhaust port 60 is provided at the bottom of the processing container 10, and an exhaust apparatus 64 is connected to the exhaust port 60 via an exhaust pipe 62. The exhaust apparatus 64 includes an automatic pressure control valve and a vacuum pump, and the exhaust apparatus 64 allows the inside of the processing container 10 to be exhausted and the inside of the processing container 10 to be maintained at a desired vacuum level. A loading and unloading port 65 for loading or unloading the substrate W into and out of the processing container 10 is provided on a side wall of the processing container 10, and this loading and unloading port 65 is configured to be opened or closed by a gate valve 66. Further, a detachable depo shield (not illustrated) for preventing etching by-products (depo) from adhering to the processing container 10 is provided along an inner wall inside the processing container 10.

A high frequency power supply 88 is electrically connected to the substrate placement table 16 which is the lower electrode. A matcher 87 is interposed on a feed line 92 for feeding a voltage to the substrate placement table 16. The high frequency power supplied from the high frequency power supply 88 preferably has a frequency of 40 MHz or more and a power in a range of 100 to 500 W. The matcher 87 is intended to match a load (plasma) impedance with an impedance of the high frequency power supply 88. That is, the matcher 87 functions to seemingly match an internal impedance of the high frequency power supply 88 with the load impedance when the plasma is generated in the processing container 10.

Further, a direct current pulse power supply 91 for applying a direct current pulse voltage is electrically connected to the substrate placement table 16 which is the lower electrode. A feed line 92 from the direct current pulse power supply 91 is connected to the feed line 89, and the direct current pulse voltage from the direct current pulse power supply 91 is applied to the substrate placement table 16 via the feed line 92 and the feed line 89. A low pass filter 90 is interposed on the feed line 92 connected to the direct current pulse power supply 91 so that the high frequency power from the high frequency power supply 88 is not supplied to the direct current pulse power supply 91. A negative electrode of the direct current pulse power supply 91 is connected to the substrate placement table 16. The direct current pulse voltage applied by the direct current pulse power supply 91 is preferably 2000 V or more as an absolute value. The direct current pulse power supply 91 is configured to be able to adjust a duty ratio and frequency of the direct current pulse voltage. The duty ratio of the direct current pulse voltage is preferably 20% or less, and more preferably, 5 to 20%. For example, the duty ratio may be about 10%. Further, the frequency of the direct current pulse voltage is preferably in a range of 100 to 1000 kHz.

A high frequency voltage from the high frequency power supply 88 and the direct current pulse voltage from the direct current pulse power supply 91 are superimposed and applied to the substrate placement table 16 which is the lower electrode.

Valves or a flow rate controller of the gas supply 50, the high frequency power supply 88, the direct current pulse power supply 91, and the like, which are components of the film forming apparatus 100, are controlled by a controller 80. The controller 80 includes a main controller with a CPU, an input apparatus, an output apparatus, a display apparatus, and a storage apparatus. Processing of the film forming apparatus 100 is controlled on the basis of a processing recipe stored in a storage medium of the storage apparatus.

### <Film Forming Method>

Next, a film forming method according to an embodiment performed by the film forming apparatus in FIG. 1 will be described.

### First Embodiment

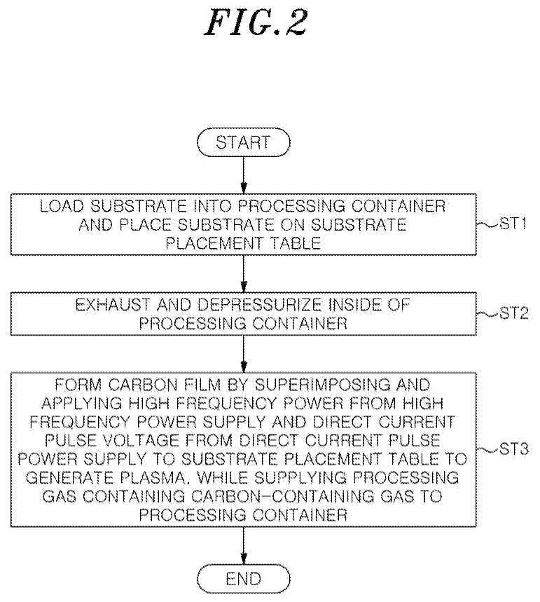

FIG. 2 is a flowchart illustrating a flow of the film forming method according to the first embodiment.

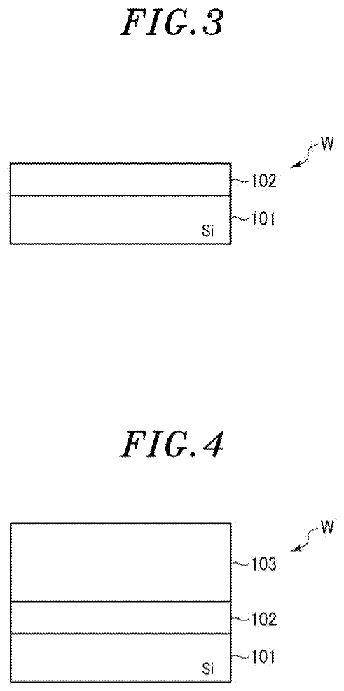

As illustrated in FIG. 2, in the present embodiment, first, the substrate W is loaded into the processing container 10 and placed on the substrate placement table 16 (step ST1). In this case, a temperature of the substrate placement table 16 is preferably set to a temperature at which a temperature of the placed substrate W is 150° C. or less. For example, a semiconductor wafer may be used as the substrate W. An example of the semiconductor wafer used as the substrate W includes a semiconductor wafer in which an underlying film 102 is formed on a Si substrate 101 as illustrated in FIG. 3. Examples of the underlying film 102 include a Si-containing film such as a SiO₂ film (for example, thermally oxidized film) or an SiNₓ film.

Next, the inside of the processing container 10 is exhausted and depressurized (step ST2). In this case, for example, the inside of the processing container 10 is exhausted while an Ar gas and/or a He gas, which are rare gases, is being supplied. In this case, pressure inside the processing container 10 is preferably 20 m Torr (2.66 Pa) or less.

In this state, a carbon film is formed by applying superimposed the high frequency power from the high frequency power supply 88 and the direct current pulse voltage from the direct current pulse power supply 91 to the substrate placement table 16, which is the lower electrode, to generate plasma while supplying a processing gas containing a carbon-containing gas to the processing container 10 (step ST3). As a specific example, a carbon film 103 is formed on the underlying film 102 of the substrate W of FIG. 3, as illustrated in FIG. 4.

FIG. 5 is a diagram illustrating a voltage waveform when superimposed high frequency (RF) power and direct current (DC) pulse voltage are applied at the time of forming a carbon film. The high frequency power from the high frequency power supply 88 is preferably 40 MHz or more in frequency and 100 to 500 W in power. Further, the direct current pulse voltage from the direct current pulse power supply 91 is preferably 2000 V or more as an absolute value, and the duty ratio is preferably 20% or less, and is more preferably 5 to 20%.

As the carbon-containing gas used for plasma generation, for example, an acetylene (C₂H₂) gas may be used. As the carbon-containing gas, a methane (CH₄) gas, ethylene (C₂H₄) gas, ethane (C₂H₆) gas, propylene (C₃H₆) gas, propene (C₃H₄) gas, propane (C₃H₈) gas, and butane (C₄H₁₀) gas, butylene (C₄H₈) gas, butadiene (C₄H₆) gas, or phenylacetylene (C₈H₆) gas may be used, in addition to the acetylene (C₂H₂) gas. Further, a mixed gas containing a plurality of gases selected from these gases may be used. Further, rare gases may be added in addition to the carbon-containing gas. An Ar gas and/or He gas may be used as the rare gas.

The carbon film formed by the plasma of carbon-containing gas generated by applying the high frequency power is an amorphous carbon film, is formed of a diamond-like carbon with a large sp³ bond ratio, and is a film with high density and high etching resistance. To this end, this is suitable as a next-generation hard mask.

On the other hand, the hard mask is required to have low film stress, in addition to high density. That is, in general, even when a film has the same stress, warpage of a substrate due to the stress of the film increases as a film thickness becomes thicker, and thus, there is concern that, when a film thickness required for the hard mask is 1 μm or more, an allowable amount of warpage (for example, 200 μm) of the substrate for executing transport or lithography is exceeded and it is difficult to execute post-processing after film formation. However, a carbon film formed by plasma of a carbon-containing gas in the related art experiences high film stress together with an increase in film density. That is, since there is a trade-off relationship between the film density and the film stress, the film stress increases as the film density increases, making it difficult to obtain a low-stress carbon film at high density.

On the other hand, in step ST3 of the present embodiment, a high-density carbon film is formed by the plasma of the carbon-containing gas by the high frequency power, and at that time, the direct current pulse voltage superimposed on the high frequency power is applied to the substrate placement table 16. Accordingly, the direct current pulse voltage is applied to the substrate W, thereby relieving the stress on the film.

Hereinafter, detailed description will be given.

Non-Patent Document 1 describes that, when high frequency power is applied to generate plasma and a carbon film is formed by plasma CVD, carbon film quality (density, sp³ ratio, and stress) has a maximum value at specific ion energy. Further, Non-Patent Document 2 describes that etching resistance of a carbon film is improved due to high density. To this end, when the density of the carbon film is made high to improve etching resistance, there is a problem is that film stress also increases at the same time. It is considered that, in the carbon film, local strain caused by a difference in lattice length due to a mixture of sp³ and sp² bonds in the film is a factor in stress. An increase in the density of the film is accompanied by an increase in the sp³ bond ratio, and the sp³ bond has a low degree of freedom of bonding, and thus, it is considered that, when the density of the film increases and the sp³ bond ratio increases, internal strain is difficult to relieve, resulting in a high-stress film.

On the other hand, at the time of forming a film using the plasma CVD, when a direct current voltage with higher ion energy than the ion energy by the high frequency power is intermittently applied, ions such as H₄, H₃⁺, C₂H₂⁺, and C₂H⁺ are radiated onto the film with high energy so that the film stress can be relieved. In this case, the film stress can preferably be set to 500 MPa or less.

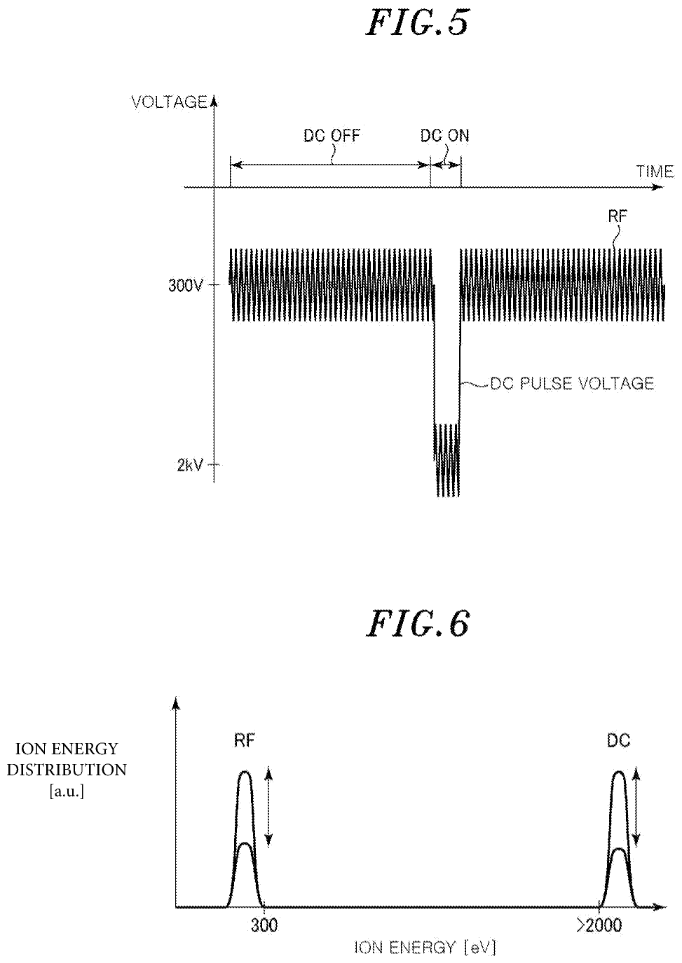

That is, in the present embodiment, a relatively low first ion energy distribution region by the high frequency power and a relatively high second ion energy distribution region by the direct current pulse voltage are formed, as illustrated in FIG. 6, so that a high-density and low-stress carbon film can be formed.

Further, the stress of the film includes both stress in a compression direction and stress in a tension direction, and low stress refers to stress having a small absolute value.

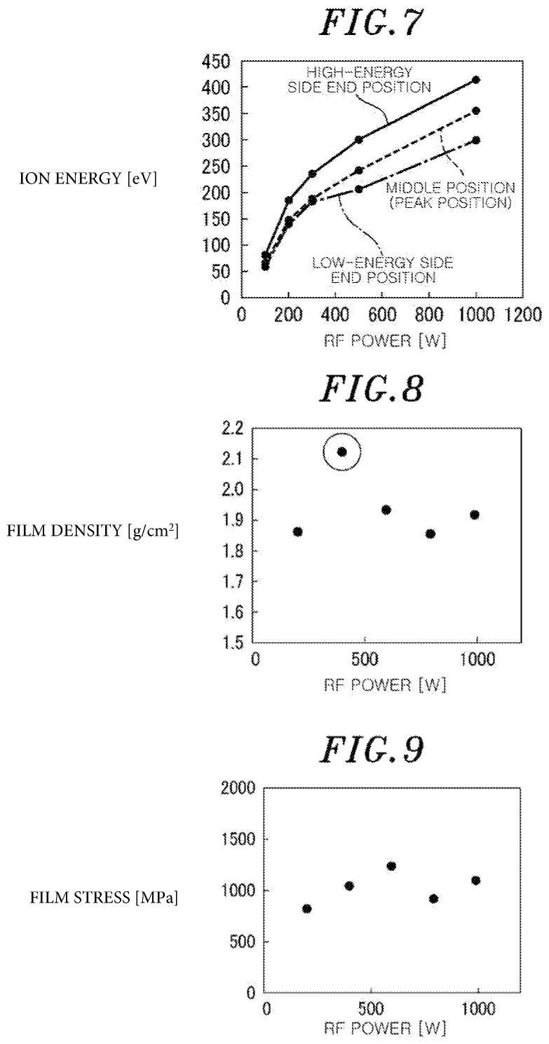

The ion energy generated by the high frequency power is preferably 300 eV or less. More preferably, the ion energy is 120 to 300 eV. This will be described on the basis of FIGS. 7 to 9. Here, the carbon film was formed by changing the RF power under conditions of temperature: 60° C., pressure: 20 mTorr (2.66 Pa), RF frequency: 40 MHz, DC pulse voltage: 1500V, C₂H₂ gas: 45 sccm, and Ar gas: 100 sccm. FIG. 7 is a diagram illustrating a relationship between RF power and ion energy at a high-energy side end position, a middle position (peak position), and a low-energy side end position in a first ion energy distribution region by high frequency power described above, with the RF power on a horizontal axis and the ion energy on a vertical axis. As illustrated in this figure, when the RF power is approximately 400 W or less, the ion energy is 300 eV or less. FIG. 8 is a diagram illustrating a relationship between the RF power and the film density, and it can be seen that the film density has a peak value when the RF power is 400 W. FIG. 9 is a diagram illustrating a relationship between the RF power and the film stress, and it can be seen that when the RF power is 600 W or less, the film stress decreases as the power decreases. It can be seen from this that it is preferable for the RF power to be 400 W or less, that is, for an ion energy distribution of the high frequency plasma to be 300 eV or less. Further, it can be seen from FIG. 7 that, when the RF power is 200 W, the ion energy is 120 to 170 eV, and it can be seen from FIGS. 8 and 9 that, when the RF power is 200 W, the film density is slightly lowered, but the film stress is low. It is derived from this that the ion energy distribution of the high frequency plasma is more preferably 120 to 300 eV.

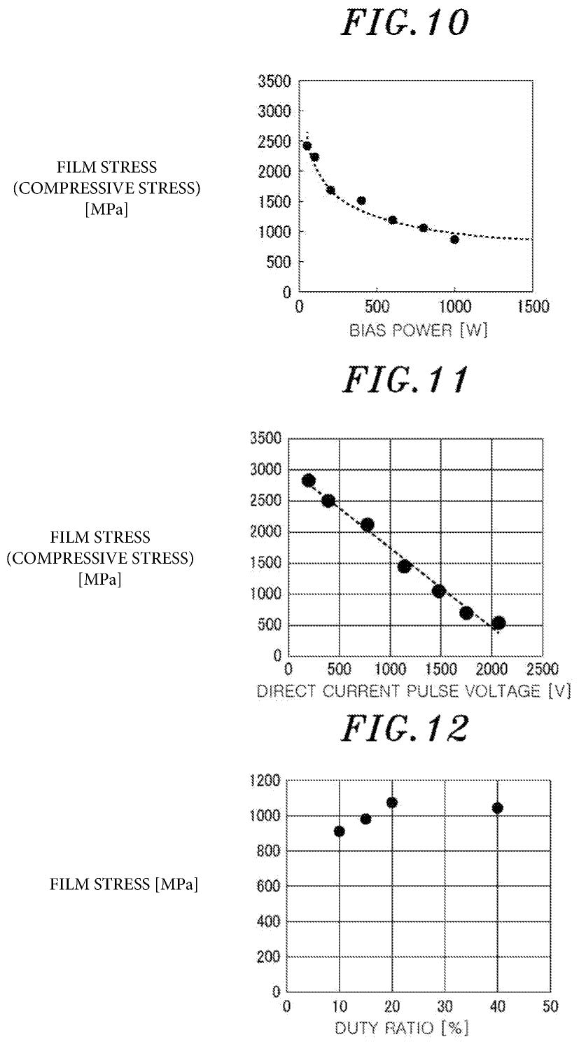

In carbon film formation, when two frequencies including a high frequency power (RF) for film formation and a high frequency power (RF) for bias are applied to the substrate placement table 16 as in the related art, it was discovered that film stress can be reduced due to an increase in power of the RF for bias. This effect tends to be greater at a lower frequency. When a frequency of the RF for bias was set to 450 kHz, a relationship between the RF for bias power and the film stress (compression stress) was as illustrated in FIG. 10. Further, here, the carbon film was formed by changing the power of the RF for bias under conditions of temperature: 60° C., pressure: 20 m Torr (2.66 Pa), frequency of RF for film formation: 40 MHZ, power: 500 W, C₂H₂ gas: 100 sccm, He gas: 100 sccm, and Ar gas: 100 sccm. As illustrated in FIG. 10, when a high frequency bias is applied, the film stress decreases, but saturates around 1000 MPa. Preferable film stress is 500 MPa or less, and an effect of decreasing the film stress cannot be said to be sufficient with the high frequency bias.

On the other hand, when the direct current pulse voltage is used, a relationship between the voltage and the film stress (compressive stress) was as illustrated in FIG. 11. Further, here, the carbon film was formed by changing the direct current pulse voltage under conditions of temperature: 60° C., pressure: 20 m Torr (2.66 Pa), frequency of RF for film formation: 40 MHz, power: 500 W, C₂H₂ gas: 100 sccm, He gas: 100 sccm, Ar gas: 100 sccm, frequency of direct current pulse: 50 kHz, and duty ratio: 10%. As illustrated in FIG. 11, when the direct current pulse voltage is applied, the stress decreases linearly, and the film stress becomes lower than 1000 MPa at 1500 V or more and becomes about 500 MPa at 2000 V.

It can be seen from FIGS. 10 and 11 that the direct current pulse voltage has a greater effect in reducing the film stress than the high frequency bias. Therefore, in the present embodiment, the direct current pulse voltage is superimposed on the high frequency power and applied to the substrate placement table 16. In this case, when the direct current pulse voltage is set to 2000 V, the film stress of about 500 MPa can be obtained in the carbon film to be formed as illustrated in FIG. 11, and thus, it is preferable for the applied direct current pulse voltage to be 2000 V or more as an absolute value.

Next, conditions for applying the direct current pulse voltage will be described. FIG. 12 is a diagram illustrating results of evaluating the dependency of a duty ratio at a frequency of 500 kHz of the direct current pulse. When the frequency is fixed and the duty ratio is changed as illustrated in FIG. 12, it can be seen that, when the duty ratio is lower, the stress tends to decrease. In particular, it can be seen that, when the duty ratio is 20% or less, the stress decreases linearly. Further, here, an RF for bias and the direct current pulse voltage were superimposed and an experiment was conducted under conditions of temperature: 60° C., pressure: 20 m Torr (2.66 Pa), frequency of RF for film formation: 40 MHz, power: 500 W, C₂H₂ gas: 100 sccm, He gas: 100 sccm, and Ar gas: 100 sccm.

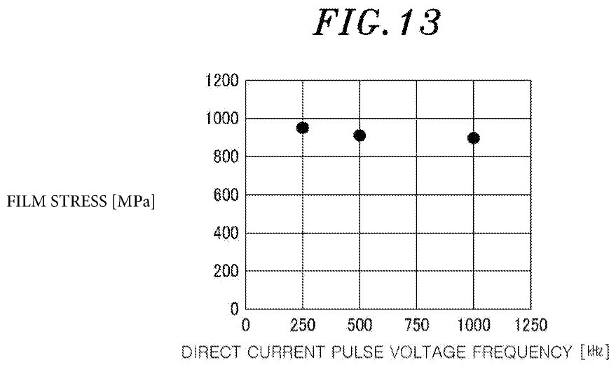

Next, the frequency of the direct current pulse voltage will be described. FIG. 13 illustrates results of an experiment of pulse frequency dependence at the same duty ratio of 10% in order to evaluate effects of the pulse frequency. As illustrated in FIG. 13, when a direct current pulse voltage frequency is changed, the film stress tends to decrease as the direct current pulse voltage frequency increases, but it can be seen that the film stress is not greatly changed by the direct current pulse voltage frequency alone. Further, here, the RF for bias and the direct current pulse voltage were superimposed and an experiment was conducted under conditions of temperature: 60° C., pressure: 20 mTorr (2.66 Pa), frequency of RF for film formation: 40 MHz, power: 500 W, C₂H₂ gas: 100 sccm, He gas: 100 sccm, and Ar gas: 100 sccm.

From this result, when the carbon film is formed through the application of the high frequency power, it is sufficient for the direct current pulse voltage to be applied during an extremely short period of time allowing opening of the film stress, and it is preferable for the duty ratio to be 20% or less as illustrated in FIG. 12. More preferably, the duty ratio is 5 to 20%. Further, the frequency of the direct current pulse voltage needs only to be a value that allows the film stress to be effectively opened, but a range of 100 to 1000 KHz is preferable since dependence of the direct current pulse voltage frequency on the film stress is small as illustrated in FIG. 13. More preferably, the frequency is 250 to 1000 kHz.

### Second Embodiment

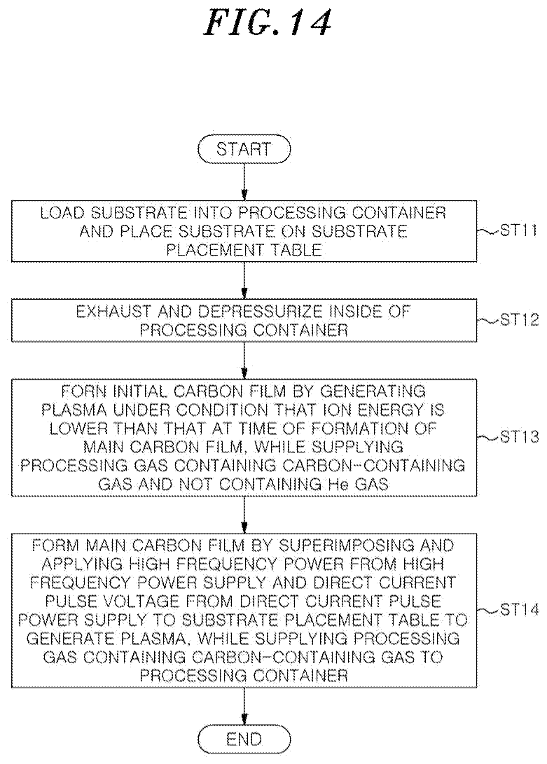

FIG. 14 is a flowchart illustrating a flow of the film forming method according to the second embodiment.

In the present embodiment, adhesion to an underlying film on which the carbon film is formed is taken into consideration.

As illustrated in FIG. 14, in the present embodiment, first, the substrate W is loaded into the processing container 10 and placed on the substrate placement table 16 (step ST11). Step ST11 is the same as step ST1 in the first embodiment, and, for example, a semiconductor wafer may be used as the substrate W. An example of the semiconductor wafer used as the substrate W includes a semiconductor wafer in which an underlying film 202 is formed on a Si substrate 201, as illustrated in FIG. 15. In the present embodiment, the same film as the underlying film 102 in the first embodiment may be used as the underlying film 202, but this is effective, especially in a case of a film in which adhesion to a carbon film such as a SiO₂ film (for example, a thermal oxidation film) is a problem.

Next, the inside of the processing container 10 is evacuated and depressurized (step ST12). In this case, the inside of the processing container 10 is exhausted, for example, while supplying the Ar gas and/or He gas which are rare gases, as in step ST2 of the first embodiment. In this case, the pressure inside the processing container 10 is preferably 20 m Torr (2.66 Pa) or less.

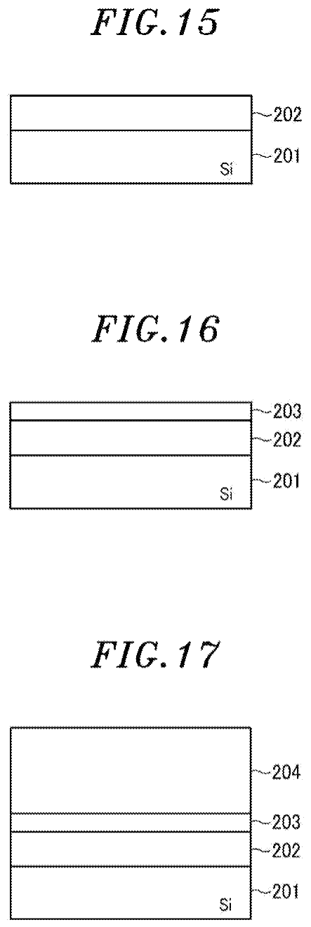

In this state, an initial carbon film is formed by generating the plasma under a condition that ion energy is lower than that at the time of formation of a next main carbon film while supplying a processing gas containing a carbon-containing gas and not containing a He gas (step ST13). As a specific example, as illustrated in FIG. 16, an initial carbon film 203 is formed on the underlying film 202 of the substrate W of FIG. 15.

As in step ST3 of the first embodiment, when the high-density and low-stress carbon film is formed by superimposing the high frequency power and the direct current pulse voltage on the substrate placement table 16, adhesion of the film may be problematic depending on the underlying film. In particular, when the underlying film is a film with poor adhesion to the carbon film, such as a SiO₂ film (for example, a thermal oxidation film), there is concern that film peeling may occur when the carbon film becomes thick. It is considered that one of factors for this is that the total ion energy increases due to the superimposing of the high frequency power and the direct current pulse voltage. Further, even when the processing gas contains a He gas, the adhesion deteriorates due to damage caused by collision of high-energy Het ions. To this end, in the present embodiment, prior to the formation of the main carbon film, the initial carbon film is formed by generating the plasma under a condition that the ion energy is lower than that at the time of forming of the main carbon film while supplying a processing gas containing a carbon-containing gas and not containing a He gas.

The total ion energy of the plasma when the initial carbon film is formed is preferably 300 eV or less. With such low ion energy, even an underlying film has a problem with the adhesion of the carbon film like a SiO₂ film, the film can be formed with high adhesion. Such plasma with low ion energy can be realized by applying only the high frequency power or applying a low direct current pulse voltage in addition to the high frequency power as a condition. From the viewpoint of ensuring adhesion, a film thickness of the initial carbon film is preferably about 10 to 100 nm and 10% or less of a total film thickness of the carbon film.

Next, as in step ST3 of the first embodiment, the main carbon film is formed by applying superimposed high frequency power and direct current pulse voltage to the substrate placement table 16 which is the lower electrode to generate the plasma while supplying a processing gas containing a carbon-containing gas to the processing container 10 (step ST14). As a specific example, as illustrated in FIG. 17, a main carbon film 204 is formed on the initial carbon film 203 of FIG. 16. Film formation conditions for the main carbon film are the same as in step ST3 of the first embodiment, and may include He gas.

According to the present embodiment, since the initial carbon film is formed on the underlying film under a condition of high adhesion, and the main carbon film is formed on the initial carbon film under the same conditions as those for the carbon film in the first embodiment, it is possible to form a high-density and low-stress carbon film without causing film peeling.

### <Other Applications>

Although the embodiments have been described above, the disclosed embodiments should be considered as examples in all respects and not as restrictive ones. The embodiments may be omitted, replaced, or changed in various forms without departing from the appended claims and the spirit thereof.

### DESCRIPTION OF REFERENCE NUMERALS

10: Processing container, 16: Substrate placement table (lower electrode), 34: Upper electrode, 50: Gas supply, 64: Exhaust apparatus, 80: Controller, 88: High frequency power supply, 91: Direct current pulse power supply, 100: Film formation apparatus, 101, 201: Si substrate, 102, 202: Underlying film, 103: Carbon film, 203: Initial carbon film, 204: Main carbon film, W: Substrate

1. A film forming method comprising:
placing a substrate on a substrate placement table provided in a processing container;
exhausting and depressurizing inside of the processing container; and
forming a carbon film on the substrate by applying superimposed high frequency power and direct current pulse voltage to the substrate placement table to generate plasma while supplying a processing gas containing a carbon-containing gas into the depressurized processing container.

2. The film forming method of claim 1, wherein the direct current pulse voltage has an absolute value of 2000 V or more.

3. The film forming method of claim 1, wherein ion energy by the high frequency power is 300 eV or less.

4. The film forming method of claim 3, wherein the ion energy by the high frequency power is 120 eV to 300 eV.

5. The film forming method of claim 1, wherein the direct current pulse voltage has a duty ratio of 20% or less.

6. The film forming method of claim 5, wherein the direct current pulse voltage has a duty ratio of 5 to 20%.

7. The film forming method of claim 1, wherein a frequency of the high frequency power is 40 MHz or more.

8. The film forming method of claim 1, wherein the processing gas includes an argon gas and/or a helium gas.

9. The film forming method of claim 1, wherein the depressurizing of the inside of the processing container includes setting pressure inside the processing container to 2.66 Pa or less.

10. The film forming method of claim 1, further comprising:
prior to forming the carbon film, forming an initial carbon film by generating plasma with a lower ion energy than that at a time of formation of the carbon film, while supplying a processing gas containing a carbon-containing gas and not containing a helium gas into the processing container in a depressurized state.

11. The film forming method of claim 10, wherein, in said forming of the initial carbon film, total ion energy of the generated plasma is 300 eV or less.

12. The film forming method of claim 10, wherein said forming of the initial carbon film includes generating the plasma by applying only the high frequency power to the substrate placement table or applying the superimposed high frequency power and direct current pulse voltage to the substrate placement table.

13. The film forming method of claim 10, wherein a film thickness of the initial carbon film is 10 to 100 nm.

14. A film forming apparatus comprising:
a processing container configured to contain a substrate;
a substrate placement table on which the substrate is placed and placed inside the processing container;
an upper electrode provided to face the substrate placement table;
a processing gas supply configured to supply a gas used for processing into the processing container;
an exhaust apparatus configured to exhaust the inside of the processing container to depressurize the inside of the processing container;
a high frequency power supply configured to supply high frequency power to the substrate placement table;
a direct current pulse power supply configured to apply a direct current pulse voltage to the substrate placement table; and
a controller,
wherein the controller is configured to control the exhaust apparatus such that the inside of the processing container is depressurized to a desired pressure in a state in which the substrate is placed on the substrate placement table, and control the gas supply, the high frequency power supply, and the direct current pulse power supply such that superimposed high frequency power and direct current pulse voltage are applied to the substrate placement table, while supplying a processing gas containing a carbon-containing gas into the processing container, thereby forming a carbon film on the substrate.

15. The film forming apparatus of claim 14, wherein the controller is configured to control such that an absolute value of the direct current pulse voltage is 2000 V or more when forming the carbon film.

16. The film forming apparatus of claim 14, wherein the controller is configured to control such that ion energy by the high frequency power is 300 eV or less when forming the carbon film.

17. The film forming apparatus of claim 14, wherein the controller is configured to control such that a duty ratio of the direct current pulse voltage is 20% or less when forming the carbon film.

18. The film forming apparatus of claim 14, wherein a frequency of the high frequency power is 40 MHz or more.

19. The film forming apparatus of claim 14, wherein, prior to forming the carbon film, the controller is configured to control the high frequency power supply such that only the high frequency power is applied to the substrate placement table or control the high frequency power supply and the direct current pulse power supply such that the superimposed high frequency power and direct current pulse voltage is applied to the substrate placement table, while supplying a processing gas containing a carbon-containing gas and not containing a helium gas into the processing container in a depressurized state, thereby forming an initial carbon film.

20. The film forming apparatus of claim 19, wherein the controller is configured to control the high frequency power supply or the high frequency power supply and the direct current pulse power supply such that total ion energy of generated plasma is 300 eV or less when forming the initial carbon film.
